(19) United States
(12) Patent Application Publication
(10) Pub. No.: US 2015/0029411 A1
(43) Pub. Date: Jan. 29, 2015

(54) TOUCH PANEL, CONDUCTIVE FILM AND METHOD FOR MANUFACTURING THE SAME

(71) Applicant: HengHao Technology Co. LTD, Taoyuan County (TW)

(72) Inventor: YI-PENG KUO, Taoyuan County (TW)

(73) Assignee: HengHao Technology Co. LTD, Taoyuan County (TW)

(21) Appl. No.: 14/044,797

(22) Filed: Oct. 2, 2013

(30) Foreign Application Priority Data
Jul. 25, 2013 (TW) 102126769

(51) Int. Cl. G02F 1/1333; G03F 7/30; H05K 1/09

(52) U.S. Cl. CPC G02F 1/13338; H05K 1/09; G03F 7/30
USPC 349/12; 174/257; 430/324

(57) ABSTRACT

A touch panel, conductive film and the method for manufacturing the same are disclosed. The conductive film may be disposed at a substrate to act as a touch sensing area. In particular, the conductive film may be formed by a method including the following steps: providing a substrate; uniformly mixing nano conductive metal with positive or negative sensitive material to form a mixture; coating the mixture over the substrate to form a wet film on the substrate; and patterning the wet film by an exposure process and a development process to form the conductive film.

### CROSS-REFERENCE TO RELATED APPLICATION

This application claims the benefit of Taiwan Patent Application No.102126769, filed on Jul. 25, 2013, in the Taiwan Intellectual Property Office, the disclosure of which is incorporated herein in its entirety by reference.

### BACKGROUND OF THE INVENTION

1. Field of the Invention

The present invention generally relates to a conductive film, in particular to a conductive film manufactured by mixing nano conductive metal with sensitive material. The present invention further relates to the touch panel having the conductive film and the method for manufacturing the conductive film.

2. Description of Related Art

Nowadays, it is necessary for many electronic devices to have both display function and touch function; hence, people keep developing new touch panel techniques. Touch panel, such as capacitive touch panel, etc., needs a conductive film as its touch sensing area. In the manufacturing process of the conventional conductive film, a metal layer, such as nano conductive metal, should be covered by sensitive material, and then the metal layer can be patterned to form the desired pattern of the conductive film by means of yellow light process.

Please refer to FIG. 1, which depicts a schematic view of the manufacturing method of the conventional conductive film. The yellow light process of the conventional manufacturing method is to transfer the pattern of a photomask to positive or negative photoresist by the UV light generated by an exposure machine. The type of the photoresist decides the result of the patterning. Then, after a development process, the pattern of the photoresist will be completely the same with the photomask, or complementary to the photomask.

As shown in FIG. 1, the yellow light process of the conventional manufacturing method needs an exposure process, a development process, an etching process and a stripping process after the photoresist layer is covered over the metal layer. Finally, the patterned metal layer can be used as conductive film. It can be seen from the above that the yellow light process of the conventional manufacturing method needs quite a few processes to pattern the metal layer, which significantly increase the manufacturing time and cost.

Taiwan Patent No. 201145309 discloses a touch panel, which provides a method for making the conductive film of the touch panel. The patent teaches that transparent gel (or solution) mixed with metal wires is coated over a flexible substrate and then a conductive film composed of interlacing metal wires is form after the transparent gel gets dry. Afterward, the conductive film composed of interlacing metal wires can be patterned to form the desired pattern. However, the above method still needs an etching process and a stripping process to form the desired pattern, which increases the manufacturing time and cost, too.

Therefore, it is imperative to develop a conductive film which can achieve the reduction of its manufacturing time and cost.

### SUMMARY OF THE INVENTION

Therefore, it is a primary objective of the present invention to provide a conductive film to solve the problem that the conventional conductive film needs complicated processes so as to reduce manufacturing time and cost.

To achieve the foregoing objective, the present invention provides a conductive film. The conductive film may be disposed on a substrate to act as a touch sensing area, wherein nano conductive metal is evenly distributed over a positive or a negative sensitive material to form a mixture, and then the mixture is coated over the substrate to form a wet film, and then the wet film is patterned by means of an exposure process and a development process to form the conductive film.

To achieve the foregoing objective, the present invention further provides a method for manufacturing a conductive film. The method may comprise the following steps: providing a substrate; evenly distributing nano conductive metal over a positive or a negative sensitive material to form a mixture; coating the mixture over the substrate to form a wet film; and patterning the wet film by an expose process and a development process to form the conductive film.

To achieve the foregoing objective, the present invention still further provides a touch panel. The touch panel may comprise a substrate and a conductive film. The conductive film may be disposed on a substrate to act as a touch sensing area, wherein nano conductive metal is evenly distributed over a positive or a negative sensitive material to form a mixture, and then the mixture is coated over the substrate to form a wet film, and then the wet film is patterned by means of an exposure process and a development process to form the conductive film.

In a preferred embodiment of the present invention, the nano conductive metal may be nano silver.

In a preferred embodiment of the present invention, the sensitive material may be a photoresist.

In a preferred embodiment of the present invention, the sensitive material may be liquid state or colloidal state.

In a preferred embodiment of the present invention, the conductive film may be applied to touch panel or touchpad.

In a preferred embodiment of the present invention, the line width of the conductive film may be less than 10 um.

In a preferred embodiment of the present invention, the thickness of the wet film may be less than 1 um.

In a preferred embodiment of the present invention, when the thickness of the conductive film is less than 1 um, the conductive film achieves gray level.

The touch panel, the conductive film and the method for manufacturing the same according to the present invention has the following advantages:

(1) In a preferred embodiment of the present invention, the wet film composed of the mixture of the nano silver and the photoresist is patterned to form the conductive film, which just needs an exposure process and a development process; therefore, the embodiment can substantially simplify the manufacturing process of the conductive film, which can effectively lower its manufacturing time and cost.

(2) In a preferred embodiment of the present invention, the conductive film is made of the mixture of nano silver and photoresist. Thus, the thickness of conductive film, due to the characters of photoresist, can be less than 1 um, and the line width of the conductive film can be less than 10 um, which effectively increases its uses.

(3) The material according to the present invention can achieve gray level with low thickness, which can distinguish the present invention from the prior art.

### BRIEF DESCRIPTION OF THE DRAWINGS

The detailed structure, operating principle and effects of the present invention will now be described in more details hereinafter with reference to the accompanying drawings that show various embodiments of the invention as follows.

FIG. 1 is a schematic view of the manufacturing method of the conventional conductive film.

FIG. 2 is a schematic view of the method for manufacturing a conductive film in accordance with the present invention.

FIG. 3 is a schematic view of one embodiment of the method for manufacturing a conductive film in accordance with the present invention.

FIG. 4 is a flow chart of one embodiment of the method for manufacturing a conductive film in accordance with the present invention.

FIG. 5 is a schematic view of one embodiment of the conductive film in accordance with the present invention.

FIG. 6 is a flow chart of the method for manufacturing a conductive film in accordance with the present invention.

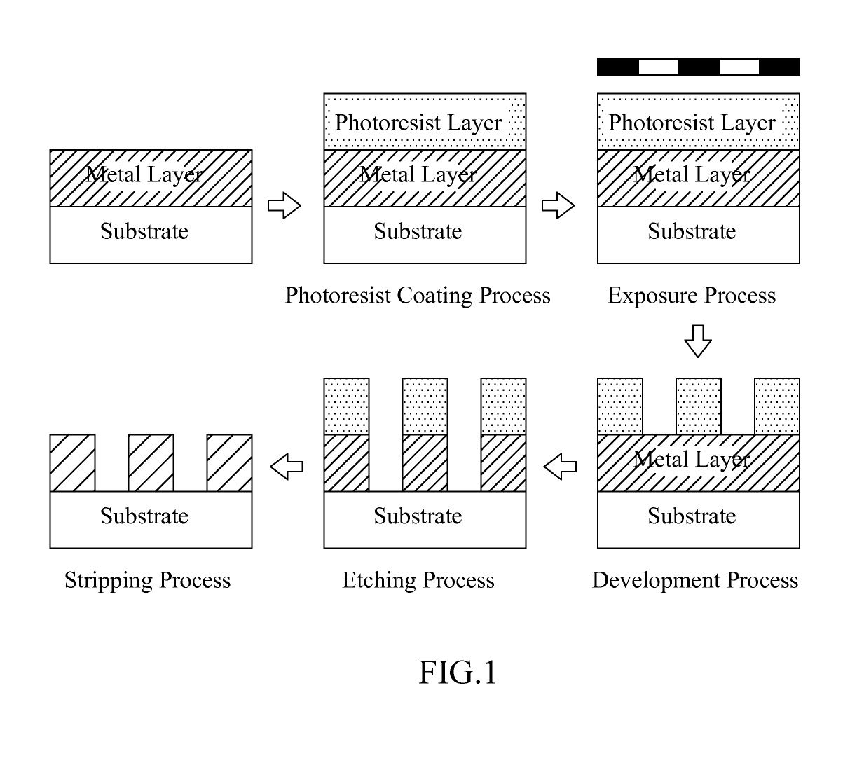

### DETAILED DESCRIPTION OF THE PREFERRED EMBODIMENTS

The technical content of the present invention will become apparent by the detailed description of the following embodiments and the illustration of related drawings as follows.

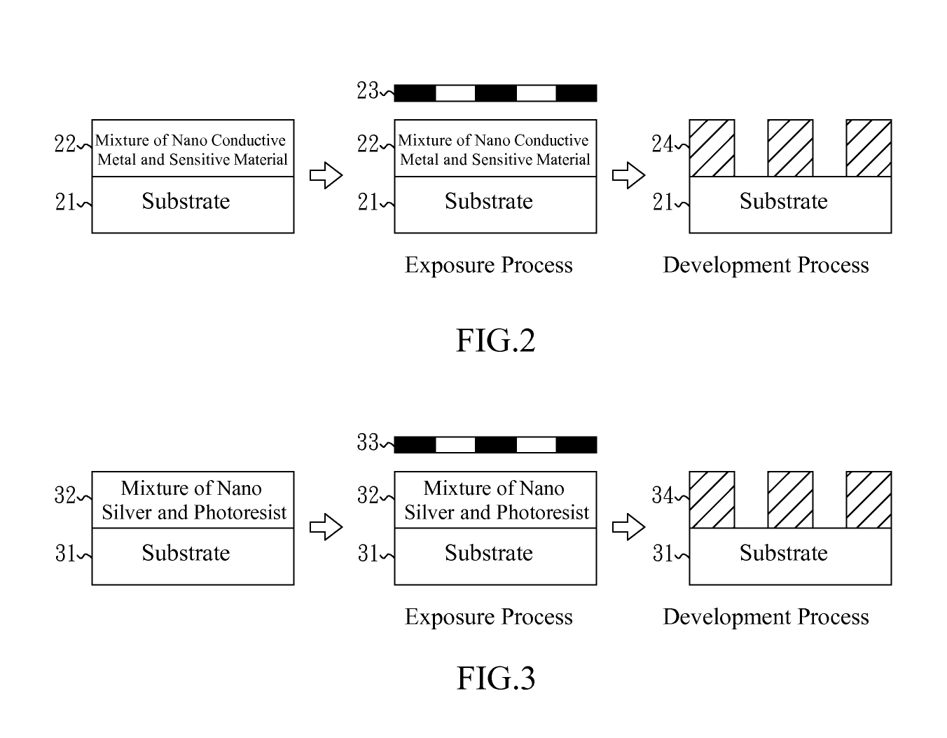

Please refer to FIG. 2 for a schematic view of the method for manufacturing a conductive film in accordance with the present invention. As shown in FIG. 2, first, a substrate 21 is provided, and then nano conductive metal is mixed with a positive or a negative sensitive material to generate a mixture 22, wherein the sensitive material may be liquid state or colloidal state. The mixture 22 of the neon conductive metal and the sensitive material may be coated over the substrate 21 via a coating process to form a wet film. Afterward, the wet film (i.e. the mixture 22) can be patterned after being exposed by a photomask and then being developed to form a conductive film 24 with particular pattern.

It can be seen form the above that the method for manufacturing a conductive film according to the present invention merely needs an exposure process and a development process to manufacture a conductive film with particular pattern. On the contrary, the conventional method needs additional processes, such like etching process and stripping process. Therefore, the present invention can definitely simplify the yellow light process, and decrease the manufacturing time and cost.

Please refer to FIG. 3 for a schematic view of one embodiment of the method for manufacturing a conductive film in accordance with the present invention. As shown in FIG. 3, in the embodiment, nano silver is mixed with a positive or a negative photoresist to form a mixture 32. Similarly, the sensitive material may be liquid state or colloidal state. In the following step, the mixture 32 of nano silver and the photoresist is coated over the substrate 31 via a coating process to form a wet film. Likewise, in the following steps, the wet film (i.e. the mixture 22) can be patterned after being exposed by a photomask and then being developed to form a conductive film 34 with particular pattern.

It is worth noting that the embodiment discloses the mixture 32 of the nano silver and the photoresist is spread over the substrate 31 to form the wet film, and then the wet film can be patterned to form the conductive film 34 by only two processes (i.e. the exposure process and the development process), which also can simplify the yellow light process, and reduce the manufacturing time and cost.

On the other hand, the nano silver cannot be electric-conductive if its content fails to reach a certain amount, which is very similar to the currently available UV-type silver paste. However, the nano silver has quite a few characteristics and advantages that the UV-type silver paste doesn't have.

For instance, the mixture of the nano silver and the photoresist can be coated over the substrate by any coating method to form a film whose thickness is less than 1 um. On the contrary, we usually need a printing process to spread the UV-type silver paste over a substrate to form a film. In this way, the thickness of this film is usually great than 5 um, which also needs complicated yellow light process and high cost.

In addition, the embodiment discloses that the conductive film is made of the mixture of nano silver and photoresist. The line width of conductive film, due to the characters of photoresist, can be less than 10 um, which is invisible to the human eye; on the contrary, the line width of conductive film is usually great than 20 um if the UV-type silver paste is used. Accordingly, the material according to the present invention has more uses and better characteristics than the UV-type silver paste. The material disclosed in the embodiment is not only applicable to touchpad, but also touch panel; in contrast, the UV-type silver paste is usually used to make the traces around the touch panel because of its material characteristics.

Furthermore, the material according to the present invention can achieve gray level with low thickness, especially below 4 um, which can increase its uses and distinguish the present invention from the conventional transparent conductive layer and non-transparent conductive layer.

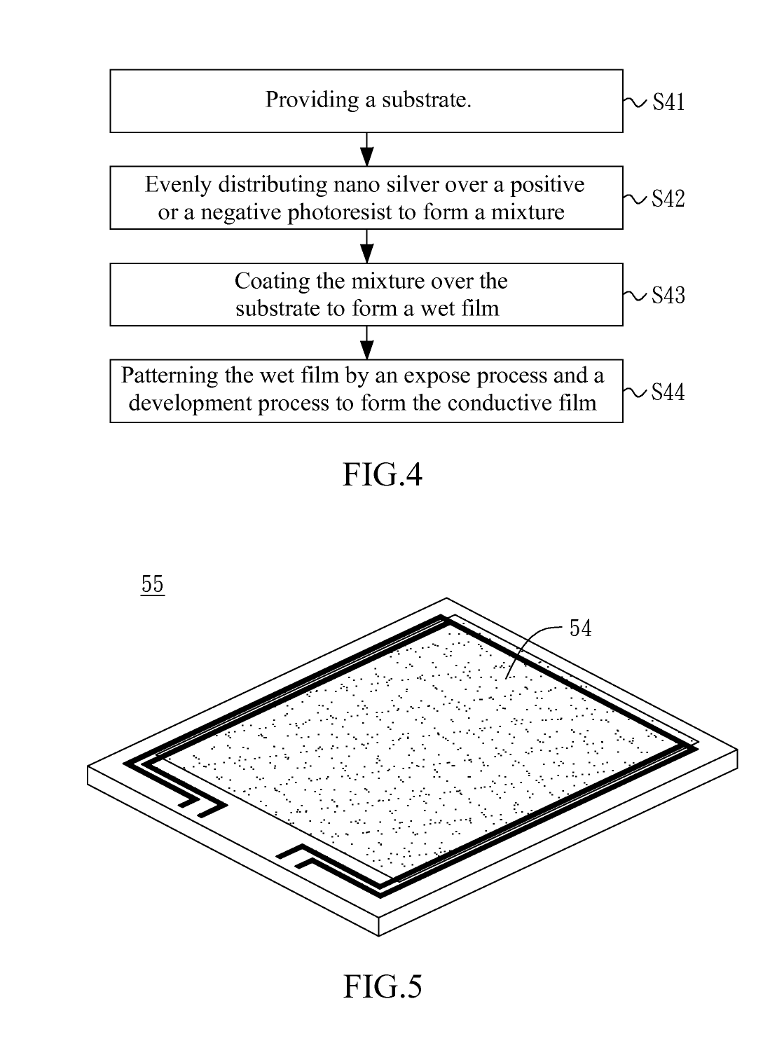

Please refer to FIG. 4 for a flow chart of one embodiment of the method for manufacturing a conductive film in accordance with the present invention. FIG. 4 is the flow chart of the embodiment of FIG. 3. The embodiment may comprise the following steps:

S41: providing a substrate.

S42: evenly distributing nano silver over a positive or a negative photoresist to form a mixture.

S43: coating the mixture over the substrate to form a wet film.

S44: patterning the wet film by an expose process and a development process to form the conductive film.

Please refer to FIG. 5, a schematic view of one embodiment of the conductive film in accordance with the present invention. The conductive film 54 according to the present invention can be installed in the touch panel 55 to act as its touch sensing area. Of course, the conductive film 54 according to the present invention is also applicable to touchpad and the like.

Although the above description about the conductive film in accordance with the present invention has illustrated the concept of the method for manufacturing a conductive film in accordance with the present invention, the following still provides the flow chart to specify the manufacturing method in accordance with the present invention.

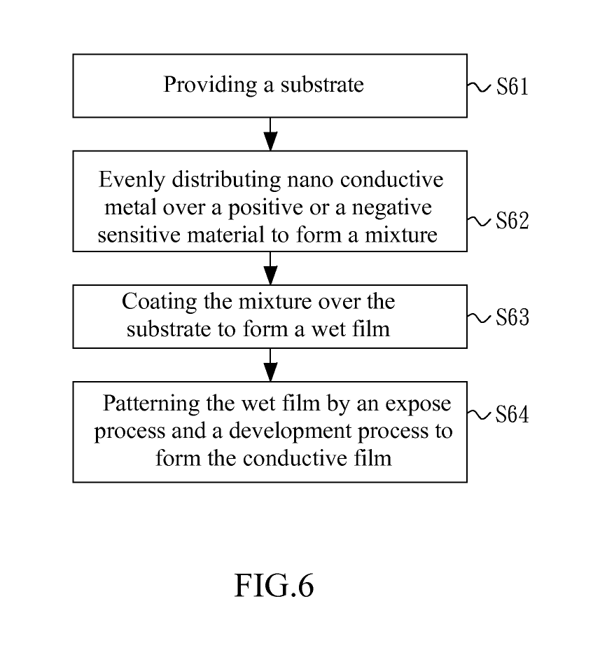

Please refer to FIG. 6 for a flow chart of the method for manufacturing a conductive film in accordance with the present invention. The method may comprise the following steps:

S61: providing a substrate.

S62: evenly distributing nano conductive metal over a positive or a negative sensitive material to form a mixture.

S63: coating the mixture over the substrate to form a wet film.

S64: patterning the wet film by an expose process and a development process to form the conductive film.

The detailed description and the exemplary embodiments of the method for manufacturing a conductive film in accordance with the present invention have been described in the description of the conductive film; therefore, they will not be repeated herein again.

In summation of the description above, a preferred embodiment of the present invention discloses that the wet film composed of the mixture of the nano silver and the photoresist is patterned to form the conductive film, which just needs an exposure process and a development process; therefore, the embodiment not only can simplify the manufacturing process of the conductive film, but also reduce its the manufacturing time and cost.

Also, a preferred embodiment of the present invention discloses that the conductive film is made of the mixture of nano silver and photoresist. The thickness of conductive film, due to the characters of photoresist, can be less than 1 um, and the line width of the conductive film can be less than 10 um, which increases its uses; hence, the present invention can definitely improve the shortcomings of the UV-type silver paste. Further, the conductive film according to the present invention can achieve gray level with low thickness, which can distinguish the present invention from the conventional conductive film and achieve the unpredictable effect.

While the means of specific embodiments in present invention has been described by reference drawings, numerous modifications and variations could be made thereto by those skilled in the art without departing from the scope and spirit of the invention set forth in the claims. The modifications and variations should in a range limited by the specification of the present invention.

What is claimed is:

1. A conductive film, disposed on a substrate to act as a touch sensing area, wherein nano conductive metal is evenly distributed over a positive or a negative sensitive material to form a mixture, and then the mixture is coated over the substrate to form a wet film, and then the wet film is patterned by means of an exposure process and a development process to form the conductive film.

2. The conductive film of claim 1, wherein the nano conductive metal is nano silver.

3. The conductive film of claim 2, wherein the sensitive material is a photoresist.

4. The conductive film of claim 3, wherein the sensitive material is liquid state or colloidal state.

5. The conductive film of claim 3, wherein the conductive film is applied to a touch panel or a touchpad.

6. The conductive film of claim 3, wherein the line width of the conductive film is less than 10 um.

7. The conductive film of claim 3, wherein the thickness of the wet film is less than 1 um.

8. The conductive film of claim 3, wherein when the thickness of the conductive film is less than 1 um, the conductive film achieves gray level.

9. A method for manufacturing a conductive film, comprising the following steps:
providing a substrate;
evenly distributing nano conductive metal over a positive or a negative sensitive material to form a mixture;
coating the mixture over the substrate to form a wet film; and
patterning the wet film by an expose process and a development process to form the conductive film.

10. The method of claim 9, wherein the nano conductive metal is nano silver.

11. The method of claim 10, wherein the sensitive material is a photoresist.

12. The method of claim 11, wherein the sensitive material is liquid state or colloidal state.

13. The method of claim 11, wherein the conductive film is applied to a touch panel or a touchpad.

14. The method of claim 11, wherein the line width of the conductive film is less than 10 um.

15. The method of claim 11, wherein the thickness of the wet film is less than 1 um.

16. The method of claim 11, wherein when the thickness of the conductive film is less than 1 m, the conductive film achieves gray level.

17. A touch panel, comprising a substrate and a conductive film, the conductive film disposed on a substrate to act as a touch sensing area, wherein nano conductive metal is evenly distributed over a positive or a negative sensitive material to form a mixture, and then the mixture is coated over the substrate to form a wet film, and then the wet film is patterned by means of an exposure process and a development process to form the conductive film.

18. The touch panel of claim 17, wherein the nano conductive metal is nano silver.

19. The touch panel of claim 18, wherein the sensitive material is a photoresist.

20. The touch panel of claim 19, wherein the sensitive material is liquid state or colloidal state.

21. The touch panel of claim 19, wherein the conductive film is applied to a touch panel or a touchpad.

22. The touch panel of claim 19, wherein the line width of the conductive film is less than 10 um.

23. The touch panel of claim 19, wherein the thickness of the wet film is less than 1m.

24. The touch panel of claim 19, wherein when the thickness of the conductive film is less than 1 m, the conductive film achieves gray level.
